(19) United States
(12) Patent Application Publication
(10) Pub. No.: US 2026/0324520 A1
(43) Pub. Date: Oct. 15, 2026

(54) Semiconductor Device and Method of Making with Fan-In on Fan-Out Wafer Level Packaging and Stacking

(71) Applicant: STATS ChipPAC Pte. Ltd., Singapore (SG)

(72) Inventors: Swain Hong Alfred Yeo, Singapore (SG); Linda Pei Ee Chua, Singapore (SG); Kai Chong Chan, Singapore (SG)

(73) Assignee: STATS ChipPAC Pte. Ltd., Singapore (SG)

(21) Appl. No.: 19/176,029

(22) Filed: Apr. 10, 2025

(51) Int. Cl. H10W 90/00; H10W 70/60; H10W 70/09; H10W 74/10; H10W 90/22

(52) U.S. Cl. CPC H10W 90/701; H10W 70/60; H10W 90/00; H10W 70/09; H10W 74/111; H10W 90/22; H10W 90/724

(57) ABSTRACT

A semiconductor packaging layer has a first semiconductor die. An encapsulant is deposited over the first semiconductor die. A fan-out interconnect structure is formed over the first semiconductor die and encapsulant. A second semiconductor die is disposed over the fan-out interconnect structure and aligned to the first semiconductor die. A second vertical interconnect structure is disposed over the fan-out interconnect structure around the second semiconductor die. A plurality of the semiconductor packaging layers is stacked to form a stacked package.

### FIELD OF THE INVENTION

The present invention relates in general to semiconductor devices and, more particularly, to a semiconductor device and method of making with fan-in on fan-out wafer-level packaging and stacking.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices commonly stack semiconductor die with vertical interconnect between the die. Stacking allows the integration of multiple similar semiconductor die to increase the overall integration of the semiconductor package. However, as semiconductor packages and die are becoming smaller and smaller, the large footprint and profile, and longer interconnect lengths, of existing stacking technology has been a limiting factor. Accordingly, a need exists for new semiconductor packages having fan-in on fan-out wafer level packaging and stacking.

### BRIEF DESCRIPTION OF THE DRAWINGS

FIGS. 1a-1h illustrate a semiconductor wafer with a plurality of semiconductor die separated by a saw street being prepared for inclusion in a stack;

FIGS. 2a-2j illustrate forming a stackable layer with two semiconductor die on a double-sided redistribution layer;

FIGS. 3a and 3b illustrate alternative layer embodiments;

FIGS. 4a and 4b illustrate a molded e-bar embodiment;

FIGS. 5a-5c illustrate forming a stacked package;

FIGS. 6a and 6b illustrate alternative stack embodiments;

FIGS. 7a-7f illustrate an alternative vertical interconnect embodiment; and

FIGS. 8a and 8b illustrate an electronic device with the stacked packages.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention’s objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

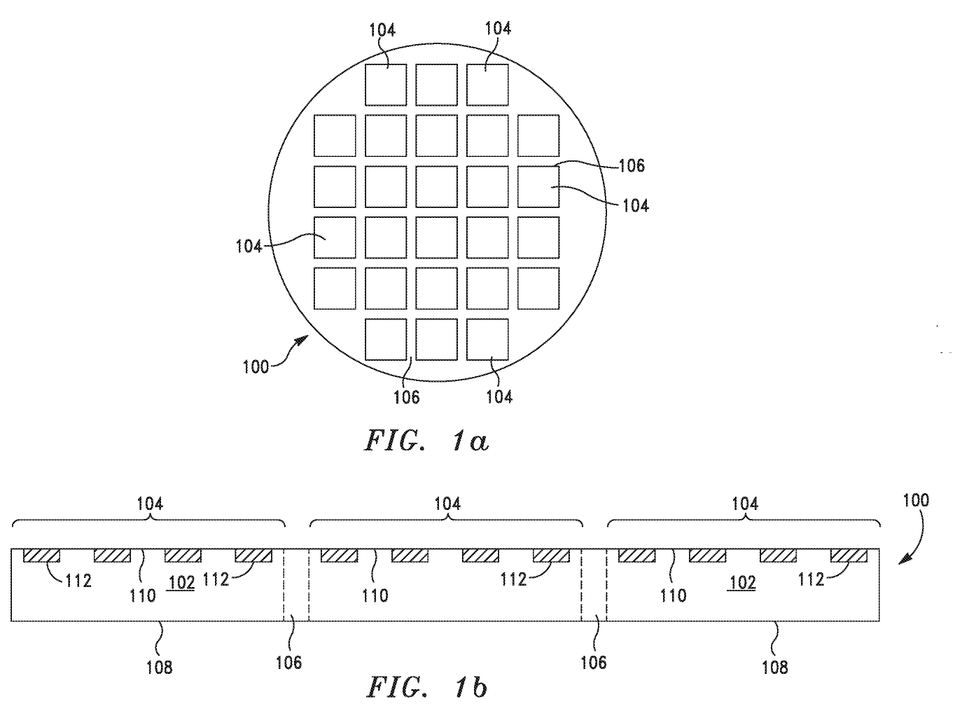

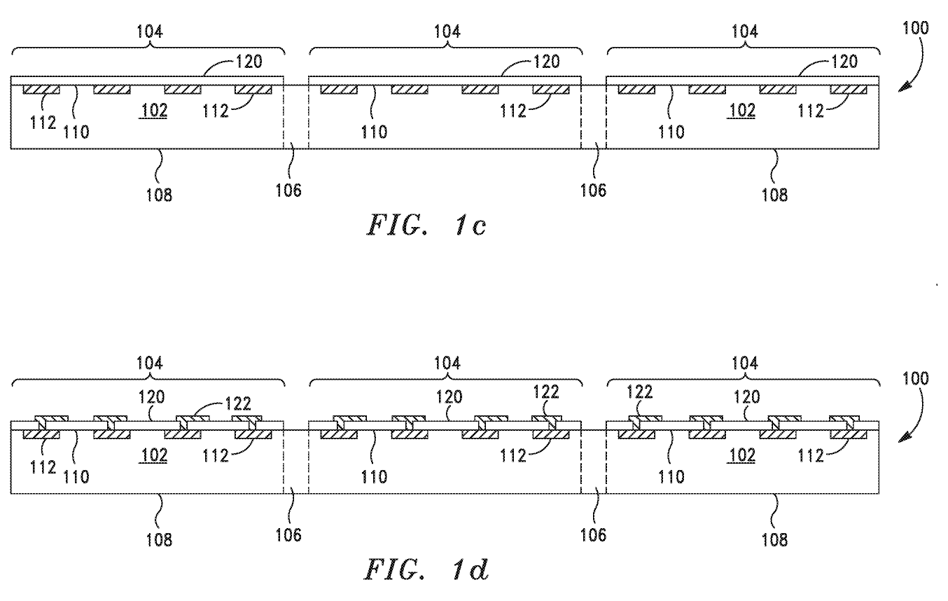

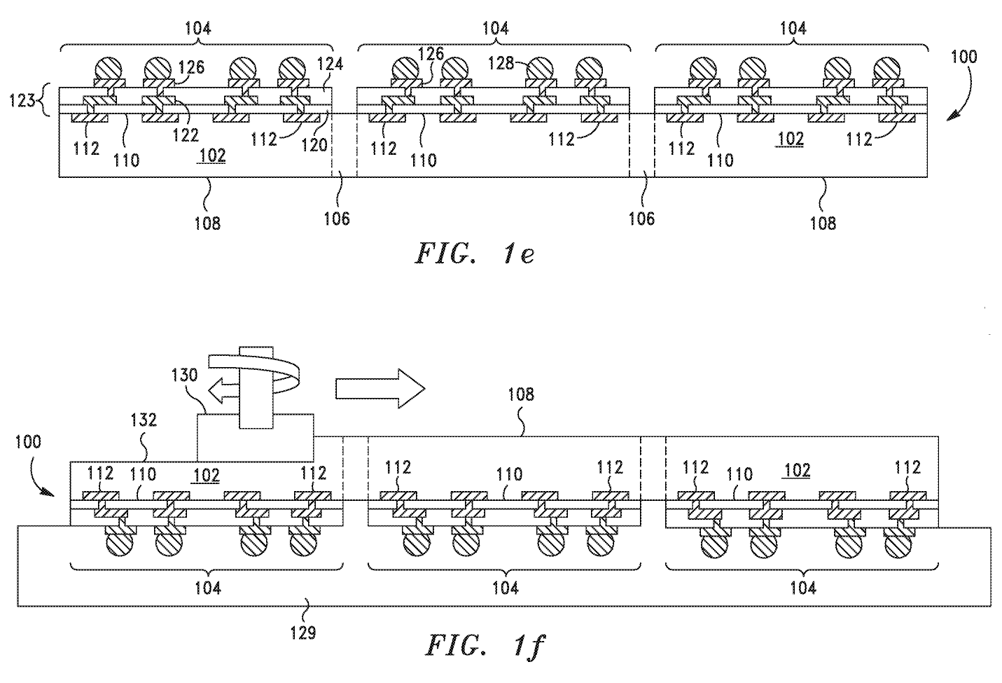

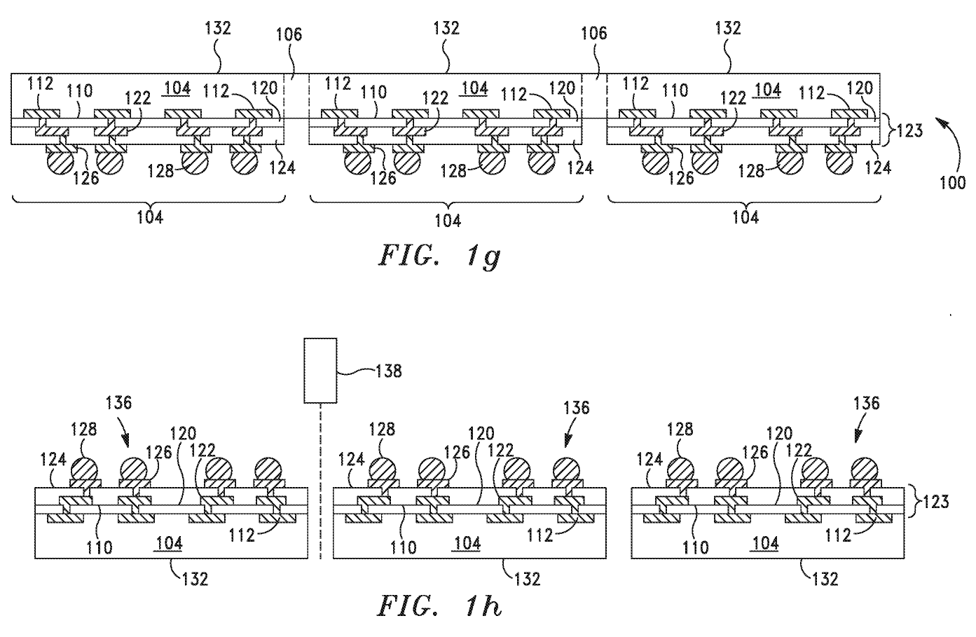

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110. Semiconductor wafer 100 will typically have several interleaved insulating layers and conductive layers to implement the desired circuit design and signal routing for each semiconductor die 104, with conductive layer 112 being the top conductive layer. Any other conductive layer mentioned herein can be formed using the same materials and methods as described for conductive layer 112.

In FIG. 1c, an insulating layer 120 is formed on wafer 100. Insulating layer 120 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other materials that have similar insulating and structural properties. Insulating layer 120 can be formed using PVD, CVD, printing, lamination, spin coating, spray coating, sintering, thermal oxidation, or other suitable means. Insulating layer 120 is optionally patterned or etched to remove the insulating layer over saw streets 106. Any insulating layer, passivation layer, dielectric layer, or encapsulant mentioned above or below can be formed using any of the materials or methods described for insulating layer 120.

In FIG. 1d, openings are formed through insulating layer 120, and any optional passivation layer remaining on active surface 110 from front-end manufacturing, to expose ohmic contacts or contact pads 112 of semiconductor die 104. The openings can be formed by chemical etching, photolithography, mechanical drilling, laser drilling, or any other suitable means. In some embodiments, a conductive layer is formed first on wafer 100, and then insulating layer 120 is formed. In cases where wafer 100 already has a passivation layer formed on active surface 110 for protection after front-end manufacturing, said passivation layer can be used as the first insulating layer of the build-up interconnect structure being formed.

A conductive layer 122 is formed on insulating layer 120 and through the openings in the insulating layer to physically and electrically couple to contact pads 112 on active surface 110. Conductive layer 122 includes conductive traces to fan-out or fan-in from semiconductor die 104 and optionally includes contact pads at both ends of the traces for connecting to the underlying contact and for subsequent formation of overlying conductive structures. Conductive layer 122 is formed using PVD, CVD, electrolytic plating, electroless plating, sputtering, or other suitable metal deposition process. Conductive layer 122 can be one or more layers of aluminum (Al), copper (Cu), tin (Sn), nickel (Ni), gold (Au), silver (Ag), or other suitable electrically conductive material.

Additional conductive layers 122 and insulating layers 120 are interleaved over wafer 100 as needed to implement the desired electrical signal routing. In the illustrated embodiment, only a single conductive layer 122 is used to fan-out or fan-in connections from semiconductor die 104. In FIG. 1e, a build-up interconnect structure 123 is completed by forming passivation or insulating layer 124 over insulating layer 120 and conductive layer 122.

Interconnect structure 123 being called a build-up interconnect structure refers to the way that the interconnect structure is formed by successively building up insulating layers and conductive layers over semiconductor wafer 100 until the desired signal routing is achieved. Insulating layer 124 can be formed using the same materials and methods mentioned above for insulating layer 120. Openings are formed through insulating layer 120 to expose contact pads or other portions of conductive layer 122.

Contact pads or under-bump metallization (UBM) pads 126 are formed on conductive layer 122 in the openings of insulating layer 124. UBM pads are optionally formed of multiple conductive layers including a wetting layer, a barrier layer, and an adhesion layer. Another passivation or solder resist layer is optionally formed over UBM pads 126. UBM pads 126 can have a flat top surface as illustrated or be formed conformally in the openings of insulating layer 124.

In some embodiments, each insulating layer and conductive layer is etched to be completely removed over saw streets 106 after being formed and before forming the next successive layer. Removing the layers between semiconductor die 104 as the layers are individually formed reduces manufacturing cost and complexity relative to singulating interconnect structure 123 with wafer 100 at a later step. Interconnect structure 123 is not formed over saw streets 106, so the eventual singulation step only has to cut through base substrate material 102. In other embodiments, insulating layers 120 and 124 are formed continuously across the entire footprint of wafer 100, including saw streets 106, and singulated along with the wafer.

An electrically conductive bump material is deposited over UBM pads 126 using an evaporation, electrolytic plating, electroless plating, ball drop, or screen-printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to UBM pads 126 using a suitable attachment or bonding process. In one embodiment, the bump material is reflowed by heating the material above its melting point to form balls or bumps 128. Bump 128 can also be compression bonded or thermocompression bonded to UBM pads 126. Bump 128 represents one type of interconnect structure that can be formed. The interconnect structure can also use bond wires, conductive paste, stud bump, micro bump, or other electrical interconnect. The term build-up interconnect structure 123 can include bumps 128 or just the underlying insulating and conductive layers.

In FIG. 1f, wafer 100 is flipped and disposed onto backgrinding tape 129 or another support or carrier. Bumps 128 sit on, or are embedded in, backgrinding tape 129. A grinder 130 is used to remove back surface 108 of wafer 100, reducing a thickness of the wafer and creating a new back surface 132. FIG. 1g shows wafer 100 after backgrinding. The entirety of wafer 100 has been made thinner by removing back surface 108 and creating a new back surface 132.

In FIG. 1h, semiconductor wafer 100 is singulated through saw street 106 using a saw blade or laser cutting tool 138 into processed semiconductor die 136. The processed semiconductor die 136 can be inspected and electrically tested for identification of known good die (KGD) or known good unit (KGU) after singulation.

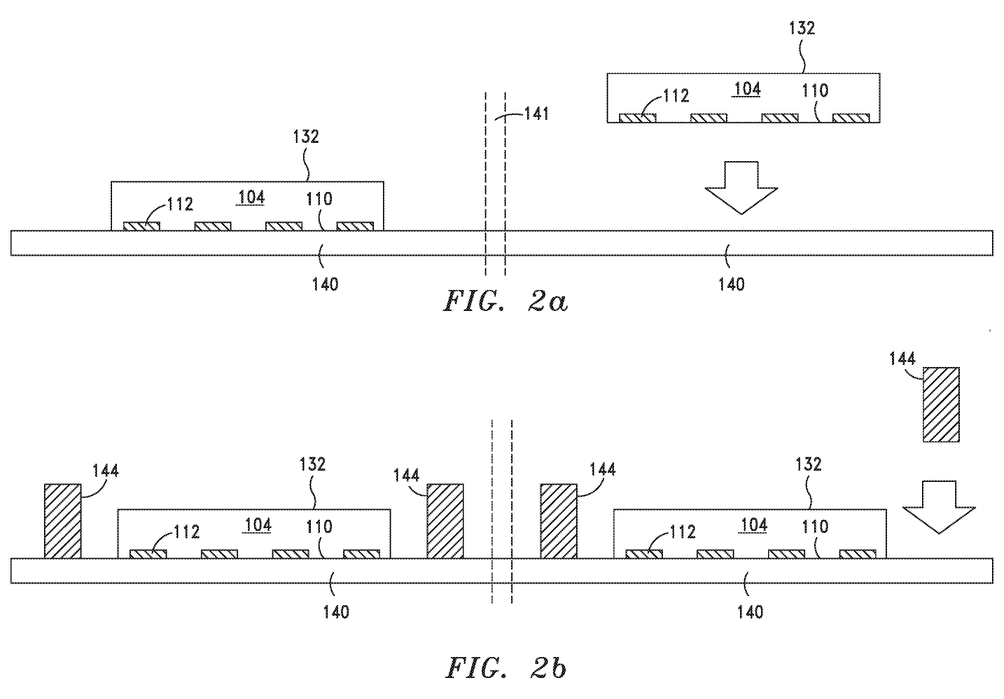

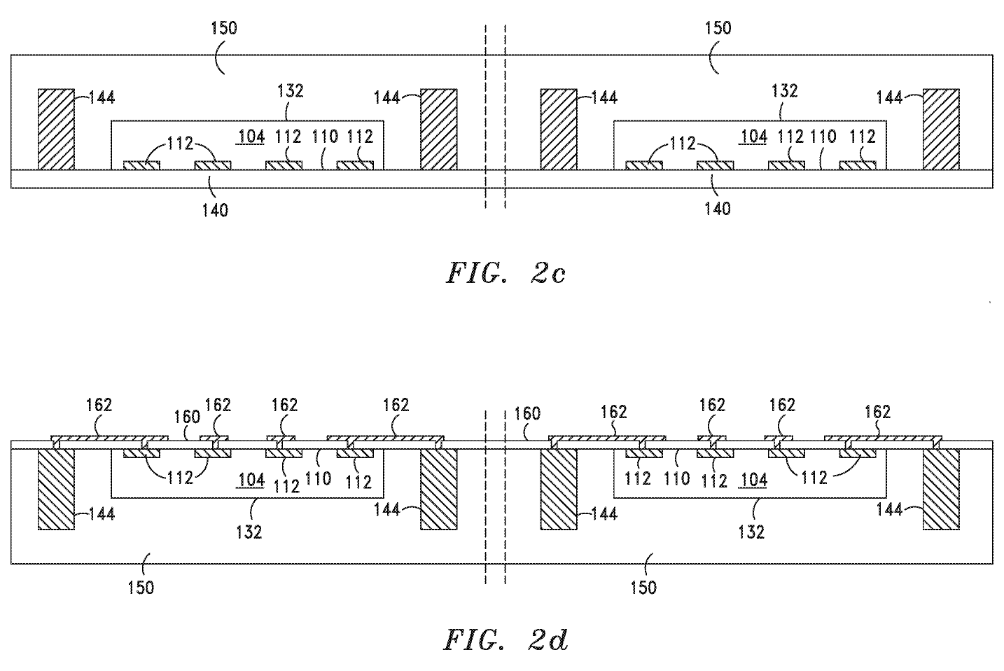

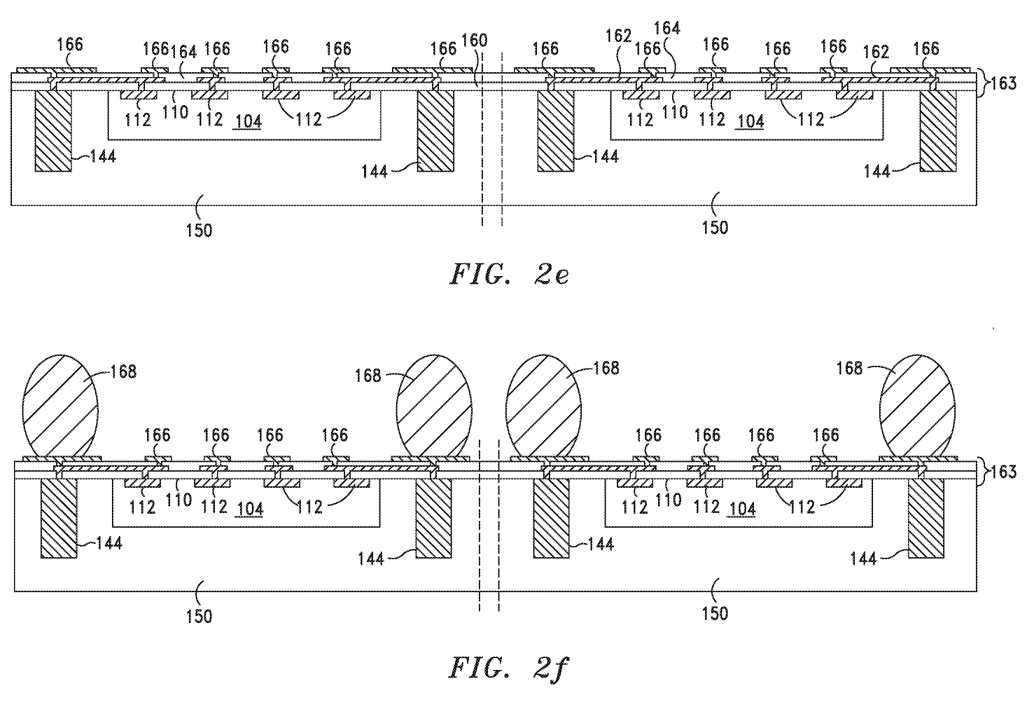

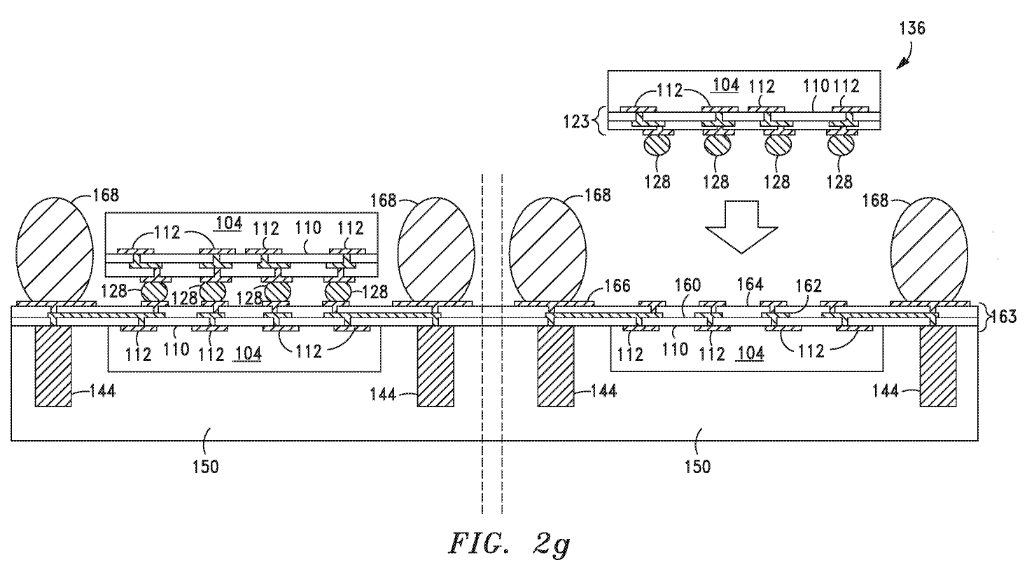

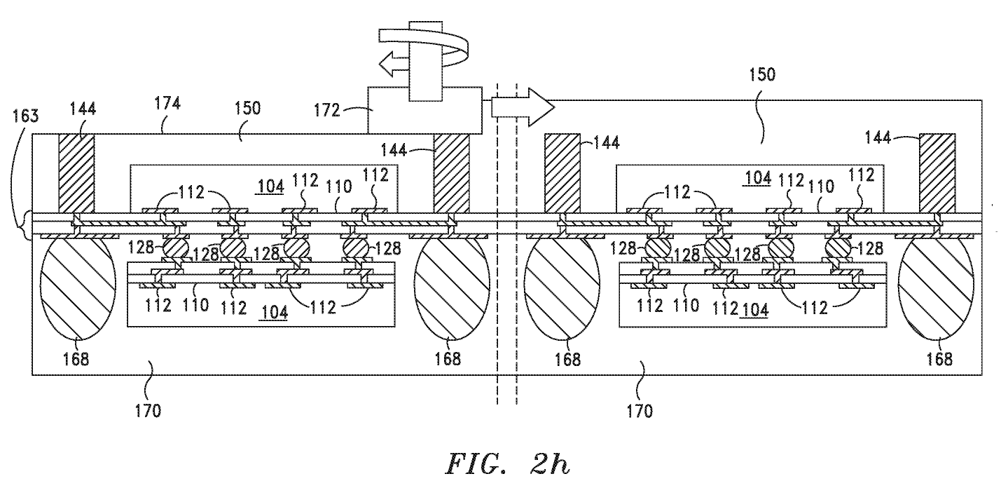

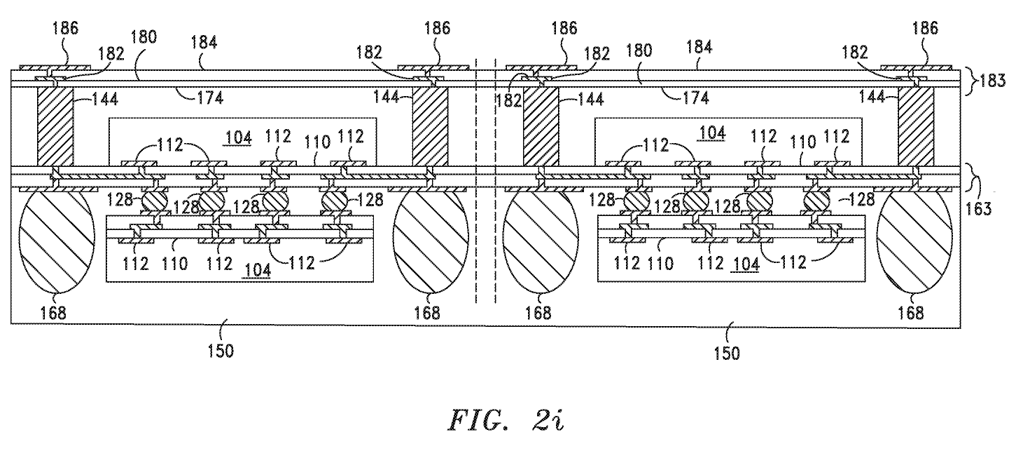

FIGS. 2a-2j illustrate the formation of a stackable layer with a first semiconductor die 104 and a second semiconductor die as part of processed semiconductor die 136. FIG. 2a shows a cross-sectional view of a carrier or temporary substrate 140 containing sacrificial base material such as silicon, polymer, beryllium oxide, glass, or other suitable low-cost, rigid material for structural support. Carrier 140 optionally has a UV, thermal, or laser release coat formed on the top surface of the carrier. The release layer can be used as a temporary adhesive to keep semiconductor die 104 and other components attached to the carrier during processing, while remaining removable.

Semiconductor die 104 are mounted onto carrier 140 with active surface 110 oriented toward the carrier. Semiconductor die 104 in FIG. 2a have been partially processed in a manner similar to processed semiconductor die 136 above, but without the formation of a build-up interconnect structure 123. Semiconductor die 104 have been backgrinded to form back surface 132 as in FIG. 1f and then singulated as shown in FIG. 1h.

Semiconductor die 104 in FIG. 2a can be the same thickness as, or a different thickness from, prepared semiconductor die 136. In some embodiments, semiconductor die 104 are not backgrinded relative to the wafer 100 in FIGS. 1a and 1b from which the semiconductor die are singulated. Any other desired electrical components can be added at this stage to be packaged along with semiconductor die 104, e.g., other semiconductor die, semiconductor packages, chiplets, or discrete active or passive components. While carrier 140 is shown as being large enough for two semiconductor die 104 to be mounted to form two separate packages separated by a saw street 141, any suitable number of semiconductor die can be processed on a common carrier.

In FIG. 2b, conductive pillars 144 are disposed over and mounted to carrier 140 around semiconductor die 104. Conductive pillars 144 can be formed separately and then disposed onto carrier 140 as shown. The conductive pillars are formed on a separate carrier using a photolithographic mask. Openings in the mask are formed to the shape desired for pillars 144 and then filled with conductive material. The mask is removed to leave conductive pillars 144. Conductive pillars 144 are then picked and placed into the desired locations on carrier 140 or into a tape-and-reel or similar storage as an intermediate step. Alternatively, pillars 144 are formed directly on carrier 140 using a photolithographic mask as just described. Conductive pillars 144 are cylindrical or another suitable shape to form vertical interconnects around semiconductor die 104.

In FIG. 2c, an encapsulant or molding compound 150 is deposited over carrier 140, semiconductor die 104, and conductive pillars 144 using a paste printing, compression molding, transfer molding, liquid encapsulant molding, vacuum lamination, spin coating, or other suitable applicator. Encapsulant 150 can be liquid or granular polymer composite material, such as epoxy resin, epoxy acrylate, or another suitable polymer, with or without a filler, e.g., silica.

Encapsulant 150 is non-conductive, provides structural support, and environmentally protects the embedded electrical components from external elements and contaminants. The resulting encapsulated assembly features encapsulant 150 forming a continuous, protective coating that adheres to carrier 140 and envelops semiconductor die 104 and conductive pillars 144. This configuration shields the delicate structures from mechanical stress, thermal cycling, and environmental factors such as humidity or dust, thereby enhancing the reliability and longevity of the semiconductor package being formed.

In FIG. 2d, the panel of encapsulant 150 and encapsulated components is flipped and carrier 140 is removed using an appropriate release mechanism. In some embodiments, carrier 140 is removed by backgrinding. Active surface 110 is exposed along with coplanar surfaces of encapsulant 150 and conductive pillars 144.

An insulating layer 160 is formed as described above for insulating layer 120, including openings formed through the insulating layer to expose contact pads 112 and conductive pillars 144. Conductive layer 162 is formed over insulating layer 160 as described above for conductive layer 122. Conductive layer 162 extends into openings of insulating layer 160 to physically and electrically contact conductive pillars 144 and contact pads 112. In addition to fanning in or out across the footprint of semiconductor die 104, as with conductive layer 122 above, conductive layer 162 also fans out to conductive pillars 144 for vertical interconnect to the other layers to be stacked in subsequent steps.

In FIG. 2e, a build-up interconnect structure 163 is completed by forming an insulating layer 164 over insulating layer 160 and conductive layer 162. UBM pads 166 are formed over insulating layer 164. Insulating layer 164 is formed as described above for insulating layer 124. UBM pads 166 are formed as described above for UBM pads 126. Build-up interconnect structure 163 is formed and operates similarly to build-up interconnect structure 123, with the addition of fanning out to conductive pillars 144.

In FIG. 2f, solder bumps 168 are formed on UBM pads 166 as described above for bumps 128. Solder bumps 168 are only formed on outer UBM pad 166 of each unit, leaving the central UBM pads 166, over the semiconductor die 104 already embedded in encapsulant 150, free for the mounting of prepared semiconductor die 136 in FIG. 2g. Prepared semiconductor die 136 from FIG. 1h are picked and placed over build-up interconnect structure 163 opposite the embedded semiconductor die 104 with build-up interconnect structure 123 oriented toward the underlying panel. Prepared semiconductor die 136 are placed down with solder bumps 128 on the free UBM pads 166 over semiconductor die 104. Semiconductor die 104 from prepared semiconductor die 136 is aligned to semiconductor die 104 already embedded in encapsulant 150. Solder bumps 128 are reflowed to physically and electrically connect prepared semiconductor die 136 to build-up interconnect structure 163, and thereby to conductive pillars 144, solder bumps 168, and the semiconductor die 104 embedded in encapsulant 150. In other embodiments, semiconductor die 104 are mounted to build-up interconnect structure 164 by solder bumps 128 directly on contact pads 112 of the die being mounted, rather than through a separate build-up interconnect structure 123.

In FIG. 2h, the panel from FIG. 2g is flipped and mounted onto a backgrinding tape 170 such that encapsulant 150 is oriented upward or otherwise made available for backside processing. A grinder 172 is used to backgrind encapsulant 150, removing a portion of the encapsulant to reduce its thickness and expose conductive pillars 144. A portion of conductive pillars 144 is removed in some embodiments to ensure the pillars are exposed and have surfaces coplanar to new back surface 174 encapsulant 150. Semiconductor die 104 can also be backgrinded at this stage, instead of or in addition to the backgrinding step shown at the wafer 100 level in FIG. 1f.

In FIG. 2i, a build-up interconnect structure 183 is formed on back surface 174 of encapsulant 150 as described above for build-up interconnect structures 123 and 163. An insulating layer 180 is formed on encapsulant 150 as described above for insulating layer 120. Openings are formed through insulating layer 180 to expose conductive pillars 144. A conductive layer 182 is formed over insulating layer 180 as described above for conductive layer 122 to fan in or fan out electrical signals from conductive pillars 144 as desired. Insulating layer 184 is formed over conductive layer 182 as described above for insulating layer 124. UBM pads 186 are formed over insulating layer 184 as described above for UBM pads 126. In other embodiments, build-up interconnect structure 163 is not formed, and instead, subsequent interconnect connects directly to conductive pillars 144 or to UBM pads formed directly on the conductive pillars.

A saw blade or laser cutting tool 188 is used to singulate the panel in FIG. 2j to form separate subpackages 190. Each subpackage 190 includes two semiconductor die 104 oriented face-to-face and interconnected to each other by build-up interconnect structure 163, which is double-sided. Build-up interconnect structure 163 also fans out to conductive pillars 144 and solder bumps 168 for vertical interconnect between layers to be stacked. Each solder bump 168 is aligned to a UBM pad 186 so that the submodules 190 can be stacked indefinitely with each solder bump 168 reflowed onto a UBM pad 186. Both semiconductor die 104 of each of the stacked subpackages 190 are connected to the other stacked layers through build-up interconnect structure 163, solder bumps 168, build-up interconnect structure 183, and conductive pillars 144.

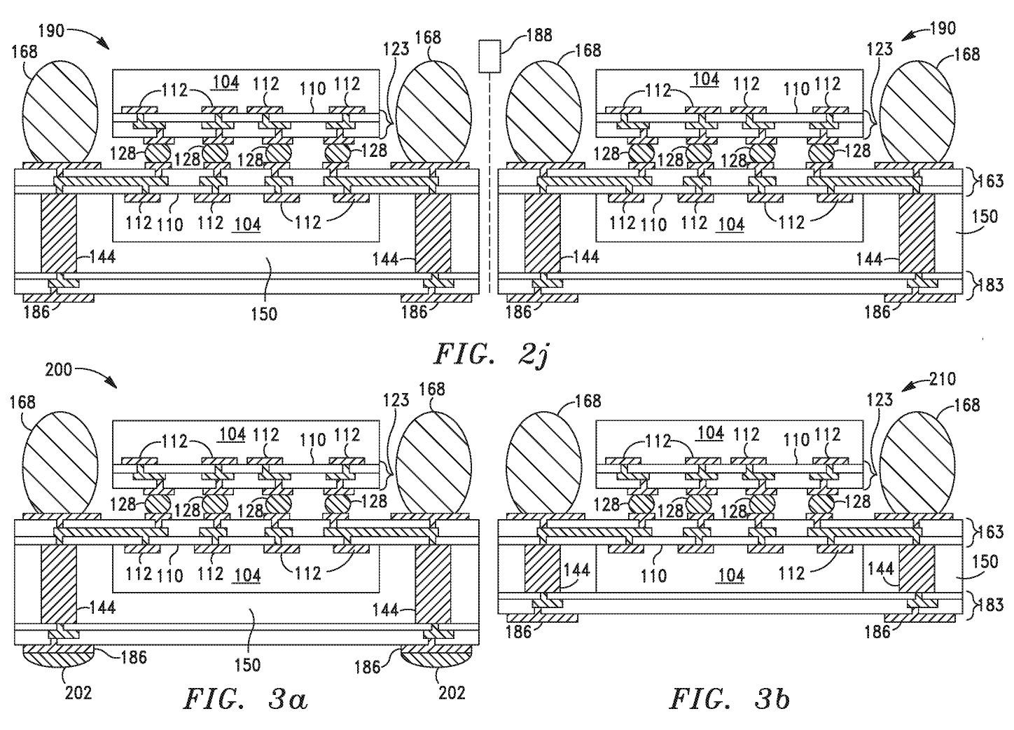

FIGS. 3a and 3b illustrate two optional features in alternative embodiments. In FIG. 3a, a subpackage 200 has solder bumps 202 formed on UBM pads 186. When the subpackages 200 are stacked, solder bumps 202 are reflowed together with solder bumps 168. Seeding UBM pads 186 with a small and relatively flat solder bump 202 helps ensure good wetting of UBM pad 186 when forming a stack. In FIG. 3b, encapsulant 150 of subpackage 210 has been thinned during the backgrinding step shown in FIG. 2h to the point of semiconductor die 104 being exposed from the encapsulant. Semiconductor die 104 can also be backgrinded at this stage instead of at the wafer level as shown in FIG. 1f. Build-up interconnect structure 183 is then formed directly on semiconductor die 104. Conductive pillars 144 can be reduced in height by the backgrinding step or initially formed shorter. Solder bumps 202 from FIG. 3a can be used in conjunction with the shorter subpackage 210 in FIG. 3b.

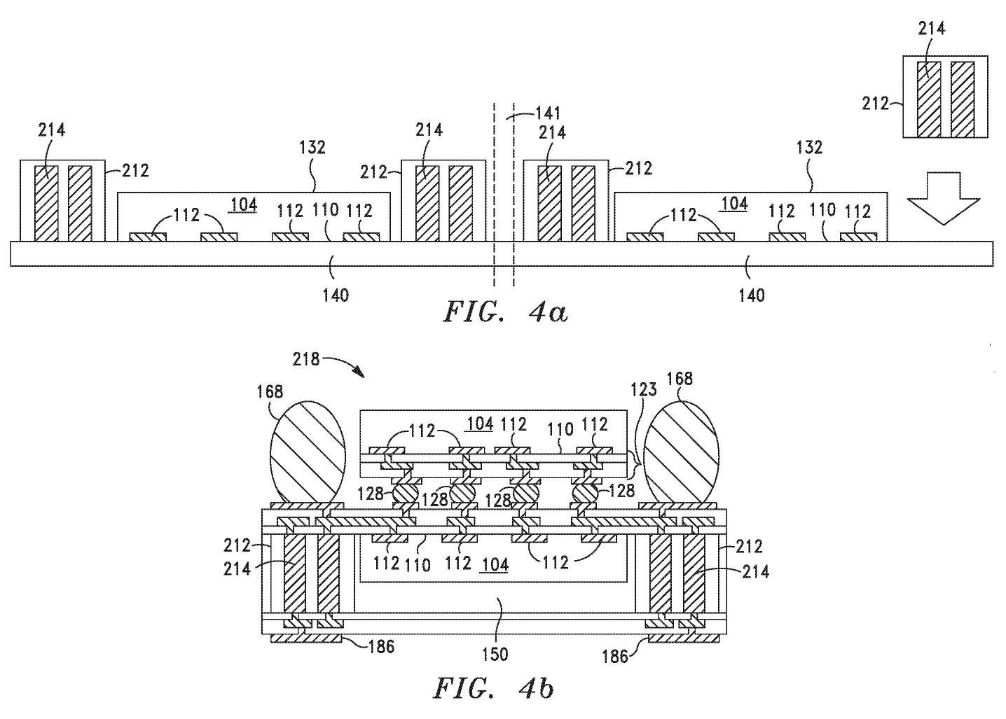

FIGS. 4a and 4b illustrate an embodiment with pre-molded conductive pillars or e-bars 212 instead of bare pillars 144. E-bars 212 have conductive pillars or vias 214 embedded in an encapsulant or molding compound. Conductive pillars 214 can be formed as described herein for conductive pillars, e.g., by disposing copper into openings of a photolithographic mask. An encapsulant is then deposited over the bars and singulated to form e-bars 212. In other embodiments, vias are formed into the encapsulant and then filled with conductive material to form pillars 214.

FIG. 4a shows e-bars 212 being disposed onto carrier 140 instead of conductive pillars 144. FIG. 4b shows a subpackage 218 made with e-bars 212. Subpackage 218 is formed as described above, except for the replacement of pillars 144 with e-bars 212. During the backgrinding step of FIG. 2h, a portion of the e-bar 212 encapsulant is removed along with encapsulant 150 to expose the tops of conductive pillars 214.

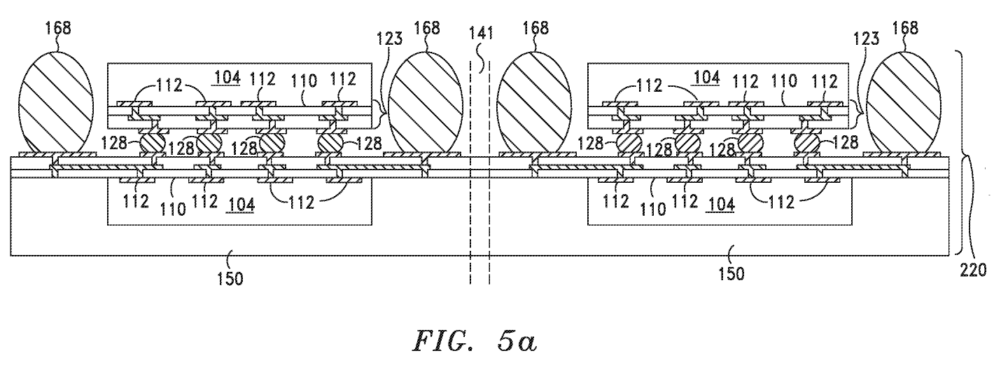

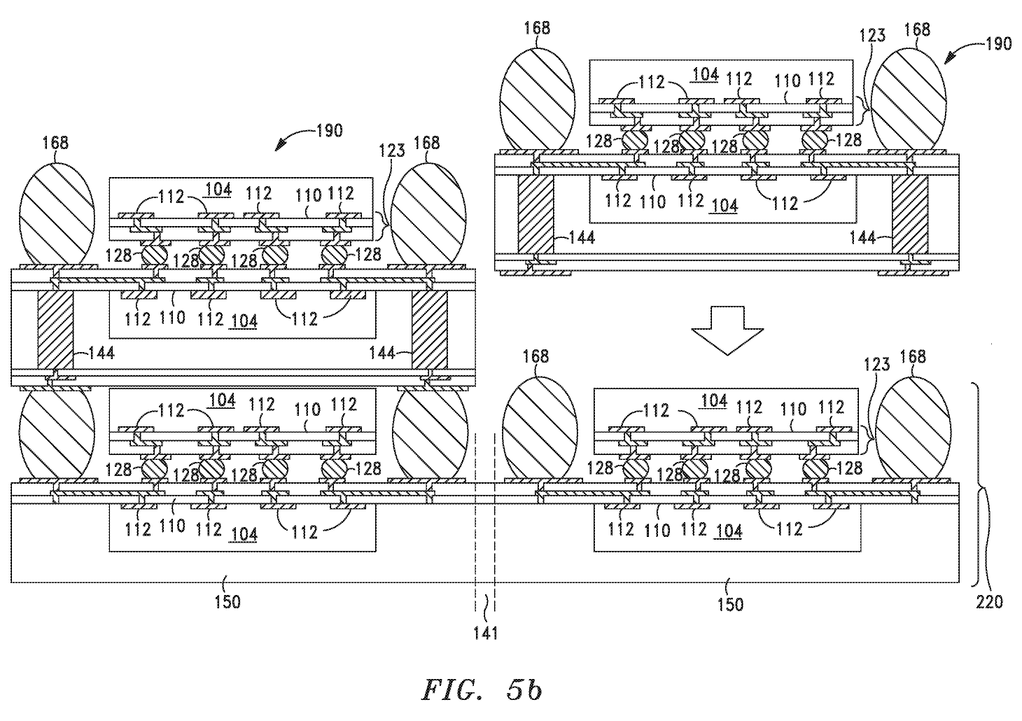

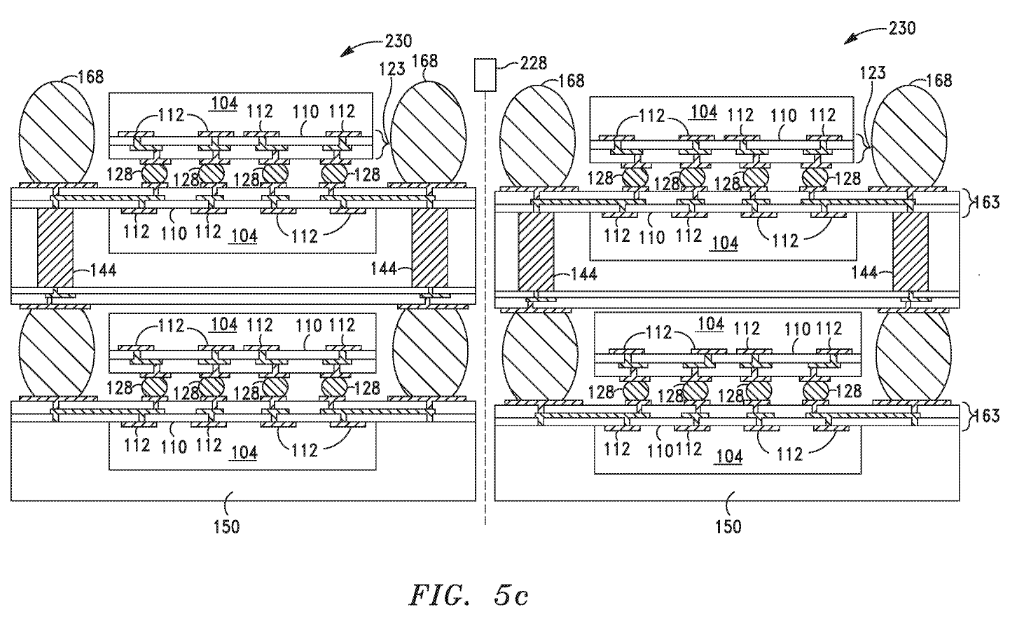

While subpackages 190, 200, 210, or 218 can be stacked indefinitely, only one end of the stack typically needs to provide an external electrical interconnect. FIGS. 5a-5c illustrate the formation of the stack with electrical interconnects on only one side. FIG. 5a shows a bottom reconstituted panel 220. A stacked package is formed using reconstituted panel 220 as the base with one or more layers of subpackages 190, 200, 210, or 218 stacked thereon. Reconstituted panel 220 is formed as shown above in FIGS. 2a-2h, except that there are no pillars 144 used. Conductive layer 162 can be formed identically to reduce the total number of mask designs, or the conductive vias that previously provided extended to conductive pillars 144 can be eliminated from the design. Encapsulant 150 is molded to the desired final thickness in some embodiments to eliminate the flipping and backgrinding step.

In FIG. 5b, subpackages 190 are picked and placed onto reconstituted wafer 220 with semiconductor die 104 from the subpackages aligned to semiconductor die 104 of the reconstituted wafer. Bumps 168 of reconstituted wafer 220 are reflowed to physically and electrically couple subpackages 190 to the reconstituted wafer. While only two side-by-side stacks are illustrated, reconstituted wafer 220 can be made larger so that many more stacks are formed at once separated by saw streets 141. While only a single subpackage 190 is stacked on each unit of reconstituted wafer 220, the subpackages can be stacked to any suitable number. Subpackages 200, 210, or 218 can be stacked on reconstituted wafer 220 instead of or in combination with subpackages 190.

Reconstituted wafer 220 is singulated in FIG. 5c using a laser cutting tool or saw blade 228 to separate a plurality of stacked packages 230 from each other. Stacked packages 230 consist of stacked modules, each having two semiconductor die 104 on opposite sides of a double-sided fan-out interconnect structure. One or more singulated submodules 190 are stacked on an unsingulated reconstituted wafer 220. Stacked packages 230 provide a small overall packaging profile and footprint with shorter interconnects for better performance. Stacking double-die devices improves scalability. Leveraging existing capability of embedded wafer-level ball-grid array and chip-on-wafer manufacturing technology makes stacked packages 230 manufacturable on existing lines.

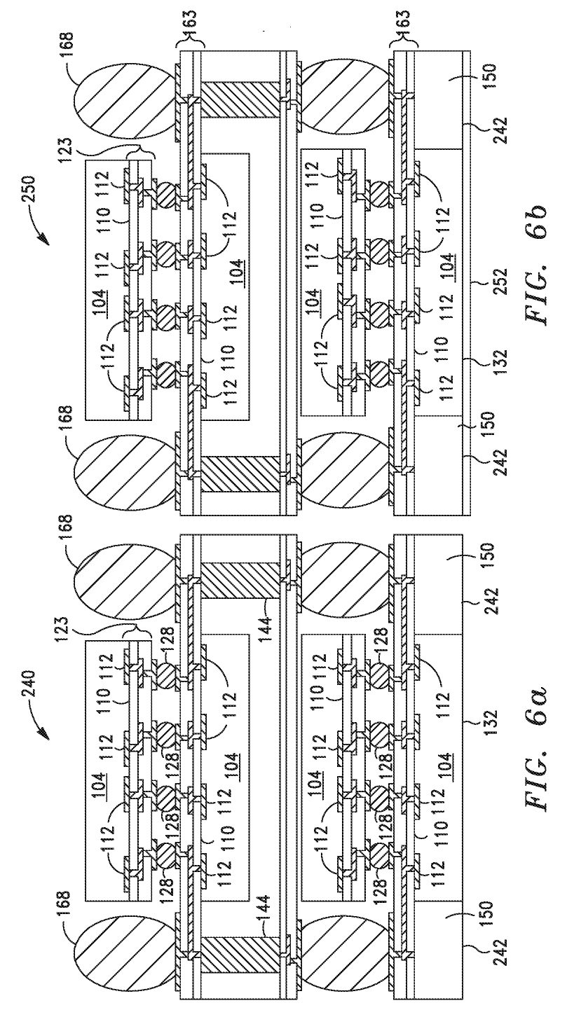

FIGS. 6a and 6b illustrate alternative embodiments for reconstituted wafer 220. In FIG. 6a, stack 240 is made with encapsulant 150 having a back surface 242 being coplanar to back surface 132 of semiconductor die 104 within the base reconstituted wafer, either by backgrinding or by using a molding process such as film-assisted molding that leaves the semiconductor die exposed. Semiconductor die 104 can be backgrinded along with encapsulant 150 in addition to or instead of backgrinding at the wafer 100 level as shown in FIG. 1f. Subpackages 210 can be used to produce an even thinner final stack. In FIG. 6b, stacked package 250 has a protective backside layer 252 added over back surfaces 242 and 132. Backside layer 252 is formed using any of the methods or materials described above for encapsulant 150 or for insulating layers generally. Backside layer 252 covers and protects the exposed semiconductor die 104.

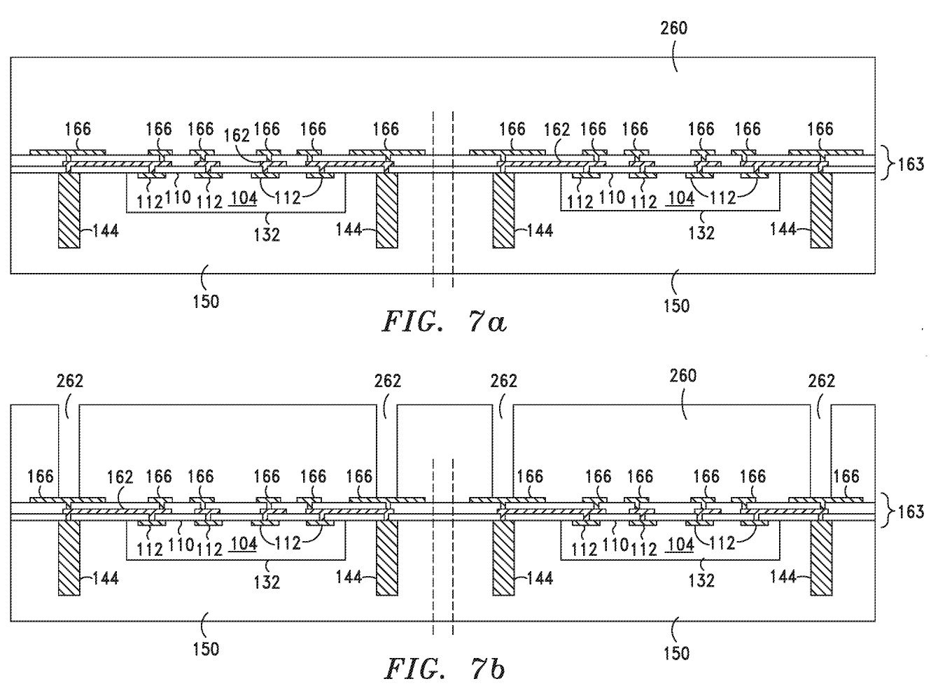

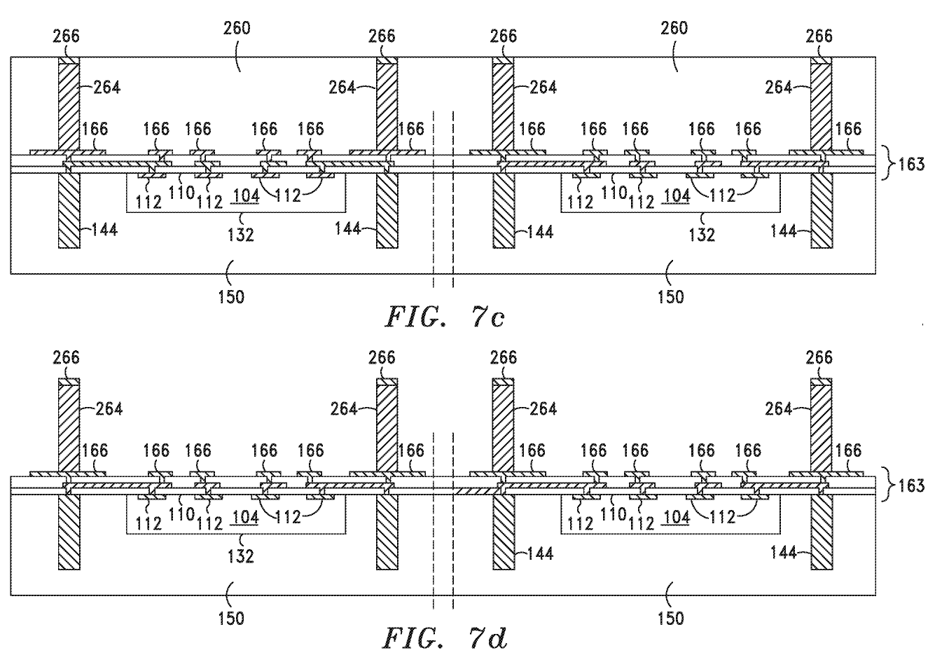

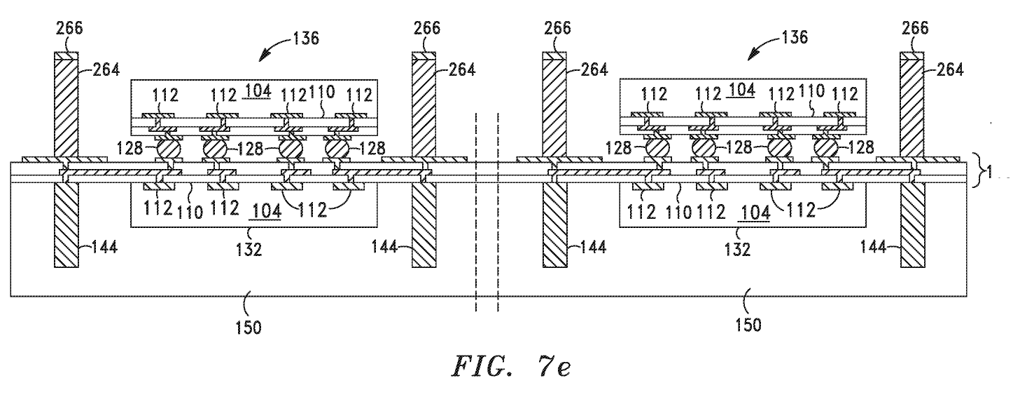

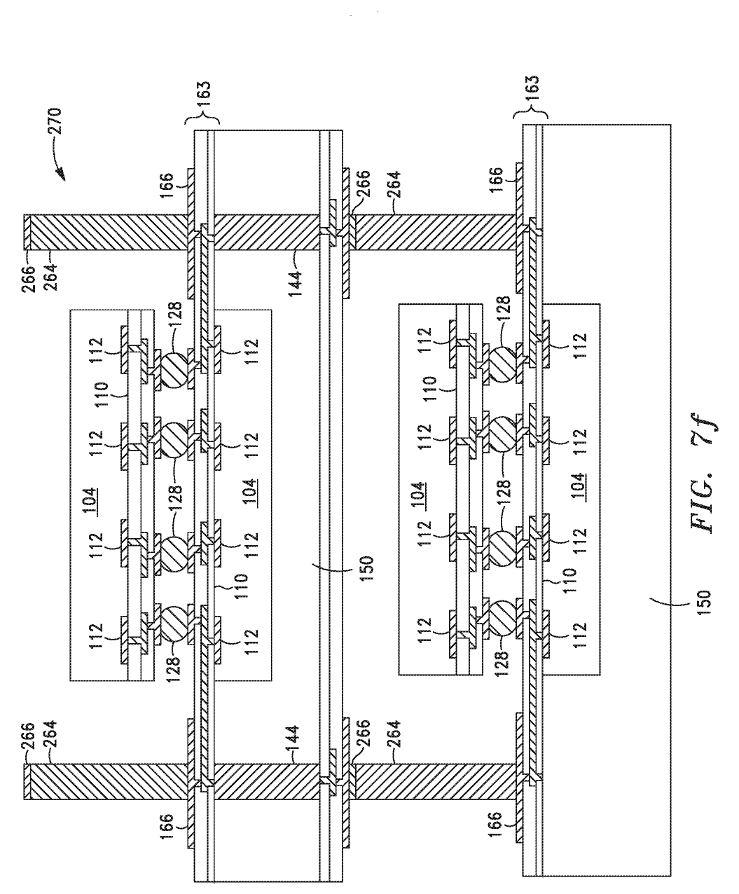

FIGS. 7a-7f illustrate an embodiment using conductive pillars for vertical interconnect instead of solder bumps 168. Continuing from FIG. 2e, a photoresist layer 260 is formed over build-up interconnect structure 163 in FIG. 7a. Photoresist layer 260 may be formed using spin coating, spray coating, lamination, film-assisted molding or any other suitable method. Materials for photoresist layer 260 include photosensitive polyimide (PSPI), epoxy-based photoresists, acrylic-based photoresists, or any other suitable material.

FIG. 7b shows via openings 262 formed completely through photoresist layer 260, exposing the outer UBM pads 166 not relied on for mounting prepared semiconductor die 136. Photolithography is used to form via openings 262 by applying a patterned mask to photoresist layer 260, exposing selected areas to light, and developing the exposed or unexposed regions to form the openings. In other embodiments, via openings 262 are formed using laser ablation, plasma etching, or any other suitable method. The dimensions and placement of via openings 262 are tailored based on the specific application and desired electrical performance.

In FIG. 7c, conductive pillars 264 are formed by filling openings 262 with conductive material. Conductive pillars 264 can be formed of any of the materials described above for conductive layer 112 and deposited using any of the above-mentioned methods. Conductive pillars 264 can be formed using a bottom-up filling technique, stopping formation of the conductive pillars with sufficient space to form solder caps 266 within the same photolithography mask 260 openings 262. Alternatively, conductive material can be deposited to overfill openings 262 and covering the top surface of photoresist layer 260 before being backgrinded or planarized to make conductive pillars 264 have top surfaces coplanar to photoresist layer 260. Thereafter, solder caps are optionally formed using another photolithographic mask, stencil printing, or another method mentioned above for forming solder bumps 168.

FIG. 7d illustrates photoresist layer 260 removed, leaving behind conductive pillars 264 and solder caps 266 on UBM pads 166. Photoresist layer 260 can be removed by wet stripping, plasma ashing, thermal decomposition, or any other suitable method. Prepared semiconductor die 136 are mounted on the centrally located UBM pads 166 in FIG. 7e as described above.

FIG. 7f illustrates a die stack 270 formed as described above, but with conductive pillars 264 replacing solder bumps 168. Conductive pillars 264 provide a solid structural feature to help maintain a consistent offset between the layers and reduce the likelihood of layers sagging.

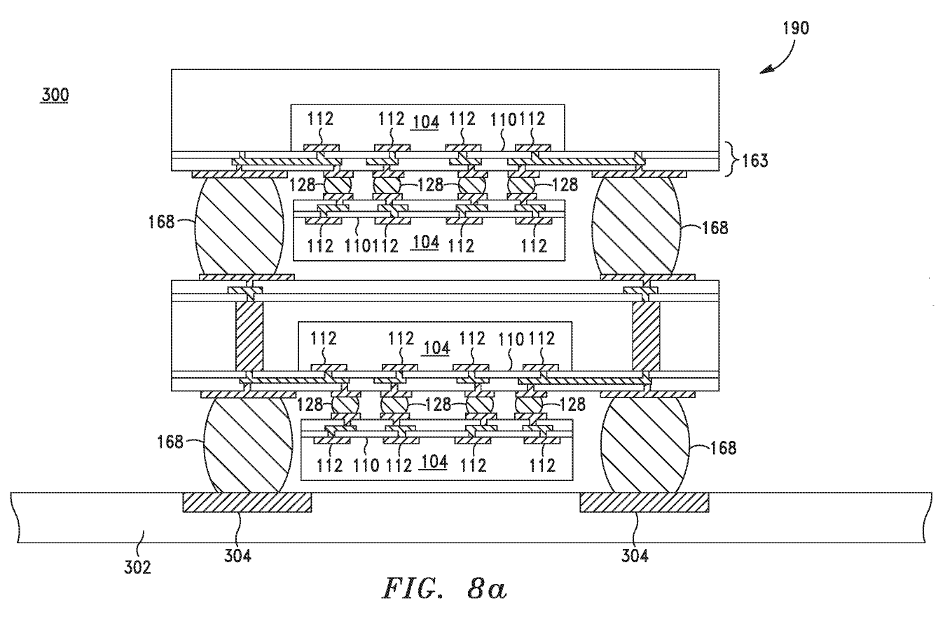

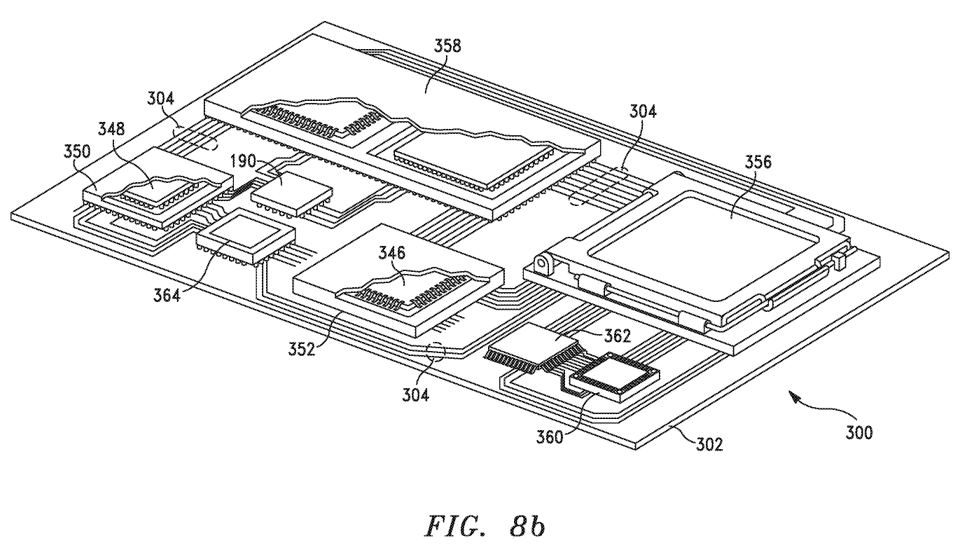

FIGS. 8a and 8b illustrate integrating the above-described stacked semiconductor packages, e.g., stacked package 190, into a larger electronic device 300. FIG. 8a illustrates a partial cross-section of stacked package 190 mounted onto a printed circuit board (PCB) or other substrate 302 as part of electronic device 300. Solder bumps 168 are reflowed onto conductive layer 304 of PCB 302 to physically attach and electrically connect the semiconductor package to the PCB. In other embodiments, thermocompression or another suitable attachment and connection methods are used. In some embodiments, an adhesive or underfill layer is used between stacked package 190 and PCB 302. Semiconductor die 104 are electrically coupled to conductive layer 304 and each other through bumps 168 and build-up interconnect structures 163.

FIG. 8b illustrates electronic device 300 having a chip carrier substrate or PCB 302 with a plurality of semiconductor packages disposed on a surface of PCB 302, including stacked package 190. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 8b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
forming a first packaging layer by,
providing a first semiconductor die,
disposing a first vertical interconnect structure adjacent to the first semiconductor die,
depositing a first encapsulant over the first semiconductor die and first vertical interconnect structure,
forming a first fan-out interconnect structure over the first semiconductor die, first vertical interconnect structure, and first encapsulant,
disposing a second semiconductor die over the first fan-out interconnect structure and aligned to the first semiconductor die, and
disposing a second vertical interconnect structure over the first fan-out interconnect structure around the second semiconductor die;
forming a second packaging layer by,
providing a third semiconductor die,
depositing a second encapsulant over the third semiconductor die,
forming a second fan-out interconnect structure over the third semiconductor die and second encapsulant,
disposing a fourth semiconductor die over the second fan-out interconnect structure and aligned to the third semiconductor die, and
disposing a third vertical interconnect structure over the second fan-out interconnect structure around the fourth semiconductor die; and
stacking the first packaging layer over the second packaging layer with the first semiconductor die and second semiconductor die electrically connected to the third semiconductor die and fourth semiconductor die through the first vertical interconnect structure and third vertical interconnect structure.

2. The method of claim 1, further including forming a build-up interconnect structure over the first encapsulant opposite the first fan-out interconnect structure, wherein the third vertical interconnect structure is coupled to the first vertical interconnect structure through the build-up interconnect structure after stacking the first packaging layer over the second packaging layer.

3. The method of claim 2, further including disposing a solder bump on the build-up interconnect structure prior to stacking the first packaging layer over the second packaging layer.

4. The method of claim 1, further including:
disposing the first semiconductor die with a back surface of the first semiconductor die exposed from the first encapsulant; and
disposing the third semiconductor die with a back surface of the third semiconductor die exposed from the second encapsulant.

5. The method of claim 4, further including forming a backside protection layer over the second encapsulant and third semiconductor die.

6. The method of claim 1, wherein the first vertical interconnect structure, second vertical interconnect structure, and third vertical interconnect structure are conductive pillars.

7. A method of making a semiconductor device, comprising:
providing a first semiconductor die;
depositing an encapsulant over the first semiconductor die;
forming a fan-out interconnect structure over the first semiconductor die and encapsulant;
disposing a second semiconductor die over the fan-out interconnect structure and aligned to the first semiconductor die; and
disposing a second vertical interconnect structure over the fan-out interconnect structure around the second semiconductor die.

8. The method of claim 7, further including disposing the first semiconductor die with a back surface of the first semiconductor die exposed from the encapsulant.

9. The method of claim 8, further including forming a backside protection layer over the back surface of the first semiconductor die and encapsulant.

10. The method of claim 7, wherein the second vertical interconnect structure is a conductive pillar.

11. The method of claim 7, further including:
disposing a first vertical interconnect structure adjacent to the first semiconductor die; and
depositing the encapsulant over the first vertical interconnect structure.

12. The method of claim 7, further including forming a build-up interconnect structure over the encapsulant opposite the fan-out interconnect structure, wherein the build-up interconnect structure is coupled to the second vertical interconnect structure.

13. The method of claim 12, further including disposing a solder bump on the build-up interconnect structure.

14. A semiconductor device, comprising:
a first packaging layer including,
a first semiconductor die,
a first vertical interconnect structure disposed adjacent to the first semiconductor die,
a first encapsulant deposited over the first semiconductor die and first vertical interconnect structure,
a first fan-out interconnect structure formed over the first semiconductor die, first vertical interconnect structure, and first encapsulant,
a second semiconductor die disposed over the first fan-out interconnect structure and aligned to the first semiconductor die, and
a second vertical interconnect structure disposed over the first fan-out interconnect structure around the second semiconductor die;
a second packaging layer including,
a third semiconductor die,
a second encapsulant deposited over the third semiconductor die,
a second fan-out interconnect structure formed over the third semiconductor die and second encapsulant,
a fourth semiconductor die disposed over the second fan-out interconnect structure and aligned to the third semiconductor die, and
a third vertical interconnect structure disposed over the second fan-out interconnect structure around the fourth semiconductor die; and
wherein the first packaging layer is stacked over the second packaging layer with the first semiconductor die and second semiconductor die electrically connected to the third semiconductor die and fourth semiconductor die through the first vertical interconnect structure and third vertical interconnect structure.

15. The semiconductor device of claim 14, further including a build-up interconnect structure formed over the first encapsulant opposite the first fan-out interconnect structure, wherein the third vertical interconnect structure is coupled to the first vertical interconnect structure through the build-up interconnect structure after stacking the first packaging layer over the second packaging layer.

16. The semiconductor device of claim 15, wherein the second vertical interconnect structure includes a solder bump.

17. The semiconductor device of claim 14, wherein:
a back surface of the first semiconductor die is exposed from the first encapsulant; and
a back surface of the third semiconductor die is exposed from the second encapsulant.

18. The semiconductor device of claim 17, further including a backside protection layer formed over the second encapsulant and third semiconductor die.

19. The semiconductor device of claim 14, wherein the first vertical interconnect structure, second vertical interconnect structure, and third vertical interconnect structure are conductive pillars.

20. A semiconductor device, comprising:
a first semiconductor die;
an encapsulant deposited over the first semiconductor die;
a fan-out interconnect structure formed over the first semiconductor die and encapsulant;
a second semiconductor die disposed over the fan-out interconnect structure and aligned to the first semiconductor die; and
a second vertical interconnect structure disposed over the fan-out interconnect structure around the second semiconductor die.

21. The semiconductor device of claim 20, further including a first vertical interconnect structure adjacent to the first semiconductor die in the encapsulant.

22. The semiconductor device of claim 21, further including a build-up interconnect structure formed over the encapsulant opposite the fan-out interconnect structure, wherein the build-up interconnect structure is coupled to the second vertical interconnect structure.

23. The semiconductor device of claim 22, further including a solder bump disposed on the build-up interconnect structure.

24. The semiconductor device of claim 20, wherein a back surface of the first semiconductor die is exposed from the encapsulant.

25. The semiconductor device of claim 24, further including a backside protection layer formed over the back surface of the first semiconductor die and encapsulant.
